(19) United States
(12) Patent Application Publication
(10) Pub. No.: US 2024/0224687 A1
(43) Pub. Date: Jul. 4, 2024

(54) ORGANIC LIGHT EMITTING DISPLAY PANEL

(71) Applicant: LG Display Co., Ltd., Seoul (KR)

(72) Inventors: Ki Min LIM, Paju-si (KR); Seung Kwang ROH, Paju-si (KR); Woo Chul CHOI, Paju-si (KR); Sang Kyoung MOON, Paju-si (KR); Dong Il CHOI, Paju-si (KR)

(73) Assignee: LG Display Co., Ltd., Seoul (KR)

(21) Appl. No.: 18/476,531

(22) Filed: Sep. 28, 2023

(30) Foreign Application Priority Data
Dec. 30, 2022 (KR) 10-2022-0190681

(51) Int. Cl. H10K 59/35

(52) U.S. Cl. CPC H10K 59/353; H10K 59/352; H10K 59/122

(57) ABSTRACT

An organic light emitting display panel includes a plurality of unit pixels, wherein each of the unit pixels includes a blue subpixel, a green subpixel, and a red subpixel radially disposed, the red subpixel is disposed at the innermost side, the blue subpixel is disposed at the outermost side, and the green subpixel is disposed between the blue subpixel and the red subpixel, thereby preventing lateral current leakage.

### CROSS-REFERENCE TO RELATED APPLICATION

This application claims the benefit of Korean Patent Application No. 10-2022-0190681, filed on Dec. 30, 2022, which is hereby incorporated by reference in its entirety.

### BACKGROUND

### Technical Field

The present disclosure relates to an organic light emitting display device, and more particularly to an organic light emitting display panel capable of preventing lateral current leakage.

### Background

As the full-scale information age approaches, displays capable of visually expressing electrical information signals have been rapidly developed. Correspondingly, various flat display devices having excellent performance, such as slimness, light weight, and low power consumption, have been developed and have rapidly replaced a conventional cathode ray tube (CRT).

There are a liquid crystal display (LCD) display, a plasma display panel (PDP) device, a field emission display (FED) device, and an organic light emitting display (OLED) device as concrete examples of flat display devices.

Among the flat display devices, an organic light emitting display device has been considered as a competitive application to achieve compaction of the device and vivid color display without necessity of a separate light source.

The organic light emitting display device includes an organic light emitting element that is independently driven for each subpixel, wherein the organic light emitting element includes a positive electrode, a negative electrode, and a plurality of organic layers provided between the positive electrode and the negative electrode.

The plurality of organic layers includes a hole injection layer, a hole transport layer, an organic light emitting layer, an electron transport layer, and an electron injection layer sequentially disposed from the positive electrode. At the organic light emitting layer, holes and electrons are substantially combined, whereby excitons are generated, and light is emitted as the generated excitons are lowered to a ground state. The other layers serve to assist in transporting holes or electrons to the organic light emitting layer.

### SUMMARY

Accordingly, the present disclosure is directed to an organic light emitting display panel that substantially achieves the desires described above.

More specifically, the present disclosure to provide an organic light emitting display panel configured such that subpixels are radially disposed, wherein a blue subpixel, which has the highest driving voltage, is disposed at the outermost side, and a red subpixel, which has the lowest driving voltage, is disposed at the innermost side, whereby it is possible to prevent lateral current leakage.

Additional features and advantages of the disclosure will be set forth in the description which follows and in part will be apparent from the description, or may be learned by practice of the disclosure. Other advantages of the present disclosure will be realized and attained by the structure particularly pointed out in the written description and claims hereof as well as the appended drawings.

To achieve the above and other advantages and in accordance with the present disclosure, as embodied and broadly described herein, an organic light emitting display panel is configured such that each unit pixel includes a blue subpixel, a green subpixel, and a red subpixel radially disposed, and the red subpixel is disposed at the innermost side, the blue subpixel is disposed at the outermost side, and the green subpixel is disposed between the blue subpixel and the red subpixel.

The red subpixel may be disposed at the innermost side in a circular shape, the green subpixel may be disposed outside the red subpixel in a ring shape having a first opening to surround the red subpixel, and the blue subpixel may be disposed outside the green subpixel in a ring shape having a second opening to surround the green subpixel.

An inner surface of the green subpixel that faces the red subpixel and an outer surface of the green subpixel may be circular, and an inner surface of the blue subpixel that faces the green subpixel and an outer surface of the blue subpixel may be circular.

An inner surface of the green subpixel that faces the red subpixel and an outer surface of the green subpixel may be circular, and an inner surface of the blue subpixel that faces the green subpixel may be circular while an outer surface of the blue subpixel may be polygonal.

An inner surface of the green subpixel that faces the red subpixel and an outer surface of the green subpixel may be circular, and an inner surface of the blue subpixel that faces the green subpixel may be circular while an outer surface of the blue subpixel may be quadrangular.

The red subpixel may be polygonal, an inner surface of the green subpixel that faces the red subpixel and an outer surface of the green subpixel may be circular, and an inner surface of the blue subpixel that faces the green subpixel may be circular while an outer surface of the blue subpixel may be polygonal.

In another aspect of the present disclosure, an organic light emitting display panel is configured such that a unit pixel includes a green subpixel and a red subpixel radially disposed and a blue subpixel disposed at one side of the green subpixel, the red subpixel is disposed at the inside, and the green subpixel is disposed at the outside.

The red subpixel may be disposed at the inside in a circular shape, the green subpixel may be disposed outside the red subpixel in a ring shape having a first opening to surround the red subpixel, and the blue subpixel may be disposed at one side of the green subpixel in a quadrangular shape.

An inner surface of the green subpixel that faces the red subpixel may be circular, and an outer surface of the green subpixel may be polygonal.

An outer surface of the green subpixel that faces the blue subpixel may not be parallel to the blue subpixel, and may be polygonal.

An outer surface of the green subpixel that faces the blue subpixel may be parallel to the blue subpixel, and the remainder of the outer surface of the green subpixel may be polygonal.

An inner surface of the green subpixel that faces the red subpixel may be circular, an outer surface of the green subpixel may be quadrangular, and the outer surface of the green subpixel that faces the blue subpixel may be parallel to the blue subpixel.

The red subpixel may be disposed at the inside in a polygonal shape, the green subpixel may be disposed outside the red subpixel in a ring shape having a first opening to surround the red subpixel, and the blue subpixel may be disposed at one side of the green subpixel having no first opening formed therein in an L shape.

In a further aspect of the present disclosure, an organic light emitting display panel is configured such that a unit pixel includes a blue subpixel, a first green subpixel, a second green subpixel, and a red subpixel, the first green subpixel and the second green subpixel are disposed at opposite sides of the red subpixel, and one of the first green subpixel and the second green subpixel is disposed between the blue subpixel and the red subpixel.

The first green subpixel and the second green subpixel may be driven by one driving thin film transistor.

It is to be understood that both the foregoing general description and the following detailed description of the present disclosure are exemplary and explanatory and are intended to provide further explanation of the disclosure as claimed.

### BRIEF DESCRIPTION OF THE DRAWINGS

The accompanying drawings, which are included to provide a further understanding of the disclosure and are incorporated in and constitute a part of this application, illustrate aspects of the disclosure and together with the description serve to explain the principle of the disclosure.

In the drawings:

FIG. 1 is an equivalent circuit diagram of an organic light emitting display panel according to an aspect of the present disclosure;

FIG. 2 is a plan view showing a unit pixel of an organic light emitting display panel according to a first aspect of the present disclosure;

FIG. 3 is a sectional view taken along line I-I′ of FIG. 2;

FIG. 4 is a plan view showing a unit pixel of an organic light emitting display panel according to a second aspect of the present disclosure;

FIG. 5 is a plan view showing a unit pixel of an organic light emitting display panel according to a third aspect of the present disclosure;

FIG. 6 is a plan view showing a unit pixel of an organic light emitting display panel according to a fourth aspect of the present disclosure;

FIG. 7 is a plan view showing a unit pixel of an organic light emitting display panel according to a fifth aspect of the present disclosure;

FIG. 8 is a plan view showing a unit pixel of an organic light emitting display panel according to a sixth aspect of the present disclosure;

FIG. 9 is a plan view showing a unit pixel of an organic light emitting display panel according to a seventh aspect of the present disclosure;

FIG. 10 is a plan view showing a unit pixel of an organic light emitting display panel according to an eighth aspect of the present disclosure;

FIG. 11 is a plan view showing a unit pixel of an organic light emitting display panel according to a ninth aspect of the present disclosure;

FIG. 12 is a plan view showing a unit pixel of an organic light emitting display panel according to a tenth aspect of the present disclosure;

FIG. 13A is a spectrum showing color coordinate change at low gradation when a blue subpixel according to a comparative example is turned on;

FIG. 13B is a spectrum showing color coordinate change at low gradation when a blue subpixel to which any one of the aspects of the present disclosure is applied is turned on;

FIG. 14A is a spectrum showing color coordinate change at low gradation when a green subpixel according to a comparative example is turned on;

FIG. 14B is a spectrum showing color coordinate change at low gradation when a green subpixel to which any one of the aspects of the present disclosure is applied is turned on; and

FIG. 15 is a view showing the CIE 1931 color coordinate system according to a comparative example and the present disclosure.

### DETAILED DESCRIPTION

Advantages and features of the present disclosure and methods of achieving the same will be more clearly understood from aspects described below with reference to the accompanying drawings. However, the present disclosure is not limited to the following aspects and may be implemented in various different forms. The aspects are provided merely to complete the disclosure of the present disclosure and to fully inform a person having ordinary skill in the art to which the present disclosure pertains of the category of the disclosure. The disclosure is defined only by the category of the claims.

In the drawings for explaining various aspects of the present disclosure, for example, the illustrated shape, size, ratio, angle, and number are given by way of example, and thus, are not limitative of the disclosure of the present disclosure. Throughout the specification, the same reference numerals designate the same constituent elements. Also, in the following description of the present disclosure, a detailed description of known functions and configurations incorporated herein will be omitted when it may make the subject matter of the present disclosure rather unclear. The terms “comprises”, “includes”, and/or “has”, used in the specification, do not preclude the presence or addition of other elements unless used along with the term “only”. The singular forms are intended to include the plural forms as well unless the context clearly indicates otherwise.

In the interpretation of constituent elements, the constituent elements are interpreted as including an error range even if there is no explicit description thereof.

In the description of the various aspects of the present disclosure, when describing positional relationships, for example, when the positional relationship between two parts is described using “on”, “above”, “below”, “aside”, or the like, one or more other parts may be located between the two parts unless the term “directly” or “closely” is used therewith.

In the description of the various aspects of the present disclosure, when describing temporal relationships, for example, when the temporal relationship between two actions is described using “after”, “subsequently”, “next”, “before”, or the like, the actions may not occur in succession unless the term “immediately” or “directly” is used therewith.

In the description of the various aspects of the present disclosure, although terms such as, for example, “first” and “second” may be used to describe various elements, these terms are merely used to distinguish the same or similar elements from each other. Therefore, in the specification, an element modified by “first” may be the same as an element modified by “second” within the technical scope of the present disclosure unless mentioned otherwise.

The respective features of the various aspects of the present disclosure may be partially or wholly coupled to and combined with each other, and various technical linkages therebetween and operation methods thereof are possible. These various aspects may be performed independently of each other, or may be performed in association with each other.

In this specification, a stack means a unit structure including a hole transport layer, an organic layer including the hole transport layer, and an organic light emitting layer disposed between the hole transport layer and an electron transport layer. The organic layer may further include a hole injection layer, an electron blocking layer, a hole blocking layer, and an electron injection layer. In addition, other different organic layers may be further included depending on the structure or design of an organic light emitting element.

An organic light emitting display panel may include red, green, and blue subpixels as a unit pixel.

Each subpixel includes a red, green, or blue organic light emitting layer, and the organic light emitting layer is generally formed using a shadow mask deposition method.

When the area of the shadow mask is large, however, a drooping phenomenon occurs due to the weight of the shadow mask, whereby yield is reduced when the shadow mask is used several times. For this reason, organic layers other than the light emitting layer are commonly continuously formed at each subpixel without the shadow mask.

In structures in which organic layers other than the light emitting layer commonly formed at each subpixel, i.e. common layers, are applied, however, current flows laterally through the common layer, which is continuous in the plane, whereby lateral current leakage occurs.

When the low-gradation blue subpixel is turned on, the red subpixel adjacent thereto is also turned on due to such lateral current leakage. Even though voltage is applied between a first electrode and a second electrode of the blue subpixel to emit pure blue light, the red subpixel adjacent to the blue subpixel is also turned on due to lateral current leakage through the common layer as well as a vertical electric field between a positive electrode and a negative electrode of the blue subpixel that is turned on.

In particular, such lateral current leakage is clearly visible upon low-gradation expression. The reason for this is that, when current flows in the organic layers common to the subpixels, the off-state red subpixel adjacent to the blue subpixel is turned on due to lateral leakage current horizontally flowing in the blue subpixel. In this case, color purity is lowered, and pure blue gradation expression is difficult.

The reason for this is that driving voltage required to turn on the red subpixel is lower than driving voltage required to turn on the blue subpixel, whereby a similar turn-on effect is achieved due to weak leakage current.

In particular, since the other color subpixel is turned on due to lateral current leakage, color mixing occurs at the time of low-gradation expression, whereby color display is not normally performed.

In addition, influence of lateral current leakage on the adjacent subpixel may increase as conductivity of a common organic layer used as the common layer increases.

Therefore, the present disclosure provides an organic light emitting display panel configured such that subpixels are radially disposed, wherein a blue subpixel, which has the highest driving voltage, is disposed at the outermost side, and a red subpixel, which has the lowest driving voltage, is disposed at the innermost side, whereby it is possible to prevent lateral current leakage.

Hereinafter, a display panel according to the present disclosure and a method of manufacturing the same will be described in detail with reference to the accompanying drawings.

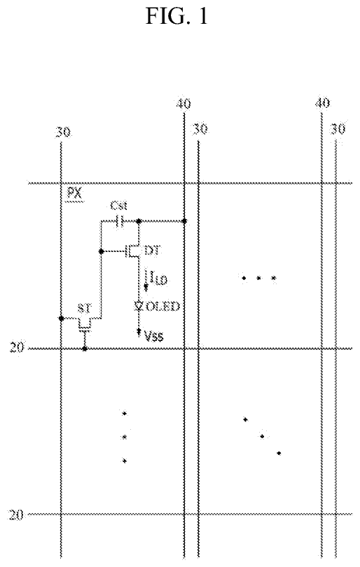

FIG. 1 is an equivalent circuit diagram of an organic light emitting display panel according to an aspect of the present disclosure.

As shown in FIG. 1, the organic light emitting display panel according to the aspect of the present disclosure includes a plurality of gate lines 20 arranged in a first direction, a plurality of data lines 30 arranged in a second direction different from the first direction, a plurality of driving voltage supply lines 40 arranged in the second direction, and a plurality of subpixels PX connected to the plurality of gate lines 20, the plurality of data lines 30, and the plurality of driving voltage supply lines 40, the plurality of subpixels PX being arranged in a matrix form.

Each subpixel PX includes a switching thin film transistor ST, a driving thin film transistor DT, a storage capacitor Cst, and an organic light emitting diode OLED. The switching thin film transistor ST, the driving thin film transistor DT, and the storage capacitor Cst may be formed on a substrate, and the organic light emitting diode OLED may be formed on the switching thin film transistor ST, the driving thin film transistor DT, and the storage capacitor Cst.

Although not shown in the figure, one subpixel PX may further include a thin film transistor and a capacitor to sense and compensate for degradation of the organic light emitting diode OLED or to sense and compensate for mobility and threshold voltage of the driving thin film transistor DT.

Each of the switching thin film transistor ST and the driving thin film transistor DT may include a gate electrode, a first electrode, and a second electrode.

The gate electrode of the switching thin film transistor ST is connected to the gate line 20, the first electrode is connected to the data line 30, and the second electrode is connected to the gate electrode of the driving thin film transistor DT and the storage capacitor Cst.

The switching thin film transistor ST transmits data voltage received from the data line 30 to the gate electrode of the driving thin film transistor DT and the storage capacitor Cst in response to a scan signal received from the gate line 20.

The gate electrode of the driving thin film transistor DT is connected to the switching thin film transistor ST, the first electrode is connected to the driving voltage supply line 40, and the second electrode is connected to the organic light emitting diode OLED. Current ILD flowing through the driving thin film transistor DT is adjusted by voltage between the gate electrode and the second electrode of the driving thin film transistor DT.

The storage capacitor Cst is connected between the gate electrode and the first electrode of the driving thin film transistor DT. The storage capacitor Cst may charge data voltage that is applied to the gate electrode of the driving thin film transistor DT such that the data voltage is maintained even after the switching thin film transistor ST is turned off to continuously turn on the organic light emitting diode OLED until next data voltage is applied.

The organic light emitting diode OLED includes an anode connected to the second electrode of the driving thin film transistor DT and a cathode connected to earth voltage or common voltage Vss. The organic light emitting diode OLED may emit light with intensity changed depending on the current ILD of the driving thin film transistor DT, thereby displaying an image.

In aspects of the present disclosure, a unit pixel including red, green, and blue subpixels will be described by way of example.

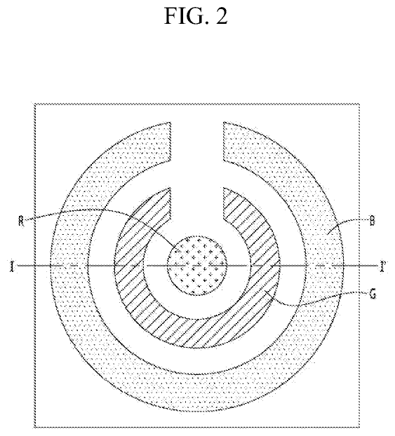

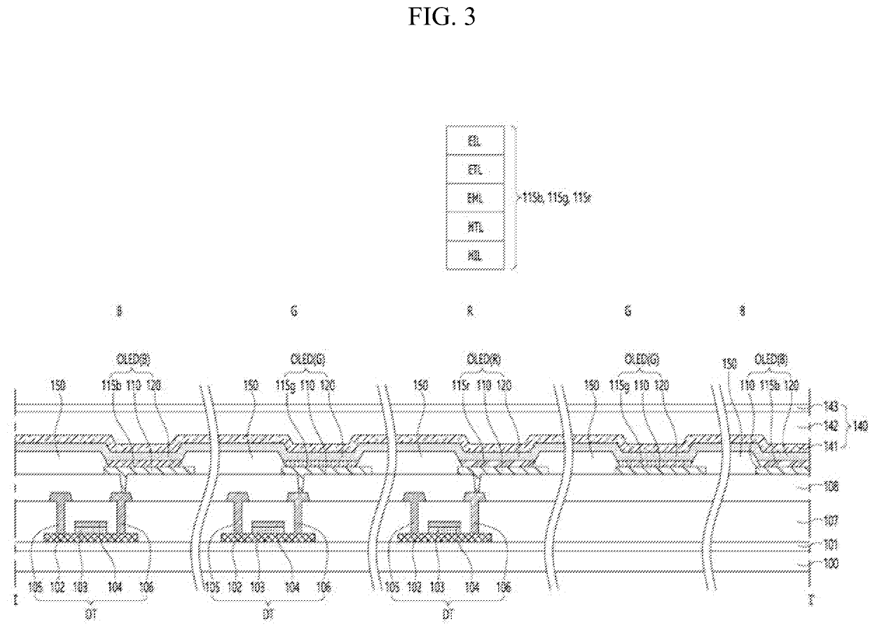

FIG. 2 is a plan view showing a unit pixel of an organic light emitting display panel according to a first aspect of the present disclosure, and FIG. 3 is a sectional view taken along line I-I′ of FIG. 2.

As shown in FIG. 2, the unit pixel of the organic light emitting display panel according to the first aspect of the present disclosure is configured such that a blue subpixel B, a green subpixel G, and a red subpixel R are radially disposed. The blue subpixel B is disposed at the outermost side, the red subpixel R is disposed at the innermost side, and the green subpixel G is disposed between the blue subpixel B and the red subpixel R.

The blue subpixel B may have the largest area among the sub-pixels, and the red subpixel R may have the smallest area among the sub-pixels. The area of the green subpixel G may be less than the area of the blue subpixel B and may be greater than the area of the red subpixel R. The blue subpixel B, the green subpixel G, and the red subpixel R are separated from each other by a bank layer 150 (shown in FIG. 3).

The red subpixel R is disposed at the innermost side in a circular shape.

The green subpixel G is spaced apart from the red subpixel R by a predetermined distance, and is disposed outside the red subpixel R in a ring shape having a first opening a to surround the red subpixel R.

The blue subpixel B is spaced apart from the green subpixel G by a predetermined distance, and is disposed outside the green subpixel G in a ring shape having a second opening b to surround the green subpixel G. The first opening a and the second opening b are located in the same direction.

Inner surfaces and outer surfaces of the blue subpixel B and the green subpixel G are circular.

The sectional structure of the unit pixel of the organic light emitting display panel according to the first aspect of the present disclosure will be described.

As shown in FIG. 3, organic light emitting diodes OLED(B), OLED(G), and OLED(R) are respectively disposed in the blue sub-pixel B, the green sub-pixel G, and the red sub-pixel R. A bank layer 150 is disposed in a non-emission portion between the blue sub-pixel B, the green sub-pixel G, and the red sub-pixel R. Each of the organic light emitting diodes OLED(B), OLED(G), and OLED(R) includes a first electrode 110 provided in light emitting portions of each sub-pixels, organic stacks 115b, 115g, and 115r located on the first electrodes 110 of the blue subpixel B, the green subpixel G, and the red subpixel R, and second electrodes 120 located on the organic stacks 115b, 115g, and 115r and the bank layers 150, respectively.

Each of the organic stacks 115b, 115g, and 115r may include a hole injection layer HIL, a hole transport layer HTL, a light emitting layer EML, an electron transport layer ETL, and an electron injection layer EIL sequentially stacked on the first electrode 110.

In FIG. 3, the organic stacks 115b, 115g, and 115r are shown as being located respectively on only the first electrodes 110 of the blue subpixel B, the green subpixel G, and the red subpixel R; however, the present disclosure is not limited thereto.

Among the layers constituting each of the organic stacks 115b, 115g, and 115r, the hole injection layer HIL, the hole transport layer HTL, the electron transport layer ETL, and the electron injection layer EIL may be commonly stacked in all of the blue subpixel B, the green subpixel G, and the red subpixel R. Among the layers constituting each of the organic stacks 115b, 115g, and 115r, only the light emitting layer EML may be located on only the first electrode of each of the blue subpixel B, the green subpixel G, and the red subpixel R.

The light emitting layer EML located on the first electrode 110 of the blue subpixel B is a light emitting layer that emits blue light, the light emitting layer EML located on the first electrode 110 of the green subpixel G is a light emitting layer that emits green light, and the light emitting layer EML located on the first electrode 110 of the red subpixel R is a light emitting layer that emits red light.

Meanwhile, in the organic light emitting display panel according to the first aspect of the present disclosure, a driving thin film transistor DT is located under each of the organic light emitting diodes OLED (B), OLED (G), and OLED (R) respectively including the first electrodes 110, the organic stacks 115b, 115g, and 115r, and the second electrodes 120 to be connected to the first electrode 110. In most cases, the driving thin film transistor DT is provided in the light non-emitting portion. When a top emission structure is applied depending on circumstances, however, the driving thin film transistor DT is provided in the light emitting portion.

The driving thin film transistor DT includes a buffer layer 101 and a light blocking layer (not shown) provided on a substrate 100, an active layer 102 provided in each subpixel area, a gate dielectric film 103 and a gate electrode 104 sequentially formed in the center of the active layer 102, and a source electrode 105 and a drain electrode 106 connected to both ends of the active layer 102.

Here, an interlayer dielectric film 107 is further provided between the active layer and flat portions of the source electrode 105 and the drain electrode 106. The interlayer dielectric film 107 has a contact hole provided to correspond to a connection part between the active layer and the source electrode 105 and the drain electrode 106.

In addition, a passivation film 108 configured to expose a part of the drain electrode 106 and to cover the remaining part of the drain electrode and the source electrode 105 is provided, and the first electrode 110 is located on the passivation film 108 while being connected to the drain electrode 106.

The first electrode 110 may cover the light emitting portion of each of the subpixels B, G, and R, and may be formed to be larger than the light emitting portion. That is, the first electrode 110 may be disposed on ac non-emission area adjacent to the light emitting portion and a part of the first electrode 110 may overlap the bank layer 150 in the non-emission portion.

An encapsulation unit 140 including a first inorganic film 141, a first organic film 142, and a second inorganic film 143 is provided on each of the organic light emitting diodes OLED(B), OLED(G), and OLED(R) of the subpixels B, G, and R.

The encapsulation unit 140 may further include one or more encapsulation pairs, each of which is constituted by an organic film and an inorganic film.

The encapsulation unit 140 prevents moisture from permeating each of the organic light emitting diodes OLED(B), OLED(G), and OLED(R), protects each of the organic light emitting diodes OLED(B), OLED(G), and OLED(R) from the outside air, and prevents foreign matter generated during processes from affecting each of the organic light emitting diodes OLED(B), OLED(G), and OLED(R).

In FIG. 3, the driving thin film transistor DT of each of the blue subpixel B, the green subpixel G, and the red subpixel R is shown as being disposed on line I-I′ for convenience of description; however, the present disclosure is not limited thereto. The driving thin film transistor DT of each of the blue subpixel B, the green subpixel G, and the red subpixel R may not be disposed on line I-I′.

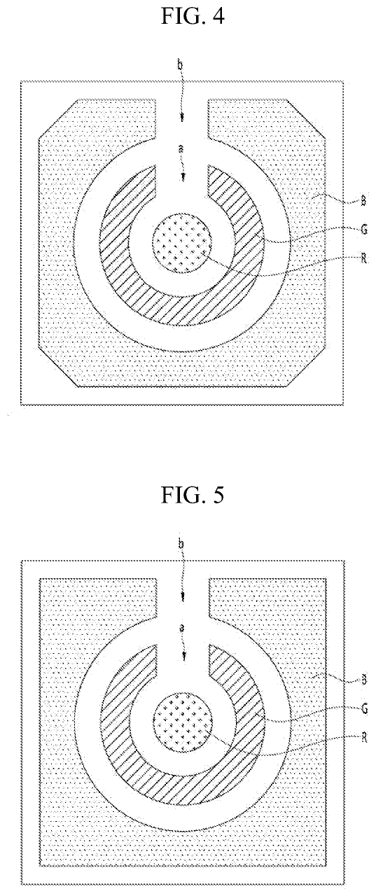

FIG. 4 is a plan view showing a unit pixel of an organic light emitting display panel according to a second aspect of the present disclosure.

As shown in FIG. 4, the unit pixel of the organic light emitting display panel according to the second aspect of the present disclosure is configured such that a blue subpixel B, a green subpixel G, and a red subpixel R are radially disposed. The blue subpixel B is disposed at the outermost side, the red subpixel R is disposed at the innermost side, and the green subpixel G is disposed between the blue subpixel B and the red subpixel R.

The blue subpixel B may have the largest area among the sub-pixels, and the red subpixel R may have the smallest area among the sub-pixels. The area of the green subpixel G may be less than the area of the blue subpixel B and may be greater than the area of the red subpixel R. The blue subpixel B, the green subpixel G, and the red subpixel R are separated from each other by the bank layer 150 (shown in FIG. 3).

The red subpixel R is disposed at the innermost side in a circular shape.

The green subpixel G is spaced apart from the red subpixel R by a predetermined distance, and is disposed outside the red subpixel R in a ring shape having a first opening a to surround the red subpixel R.

The blue subpixel B is spaced apart from the green subpixel G by a predetermined distance, and is disposed outside the green subpixel G in a ring shape having a second opening b to surround the green subpixel G. The first opening a and the second opening b are located in the same direction.

An inner surface and an outer surface of the green subpixel G are circular.

The blue subpixel B is polygonal. Specifically, an inner surface of the blue subpixel B that faces the green subpixel G is circular, and an outer surface of the blue subpixel B is polygonal.

The second aspect is identical in other constructions to the first aspect described with reference to FIGS. 2 and 3, and therefore a description of the identical constructions will be omitted.

FIG. 5 is a plan view showing a unit pixel of an organic light emitting display panel according to a third aspect of the present disclosure.

As shown in FIG. 5, the unit pixel of the organic light emitting display panel according to the third aspect of the present disclosure is configured such that a blue subpixel B, a green subpixel G, and a red subpixel R are radially disposed. The blue subpixel B is disposed at the outermost side, the red subpixel R is disposed at the innermost side, and the green subpixel G is disposed between the blue subpixel B and the red subpixel R.

The blue subpixel B may have the largest area among the sub-pixels, and the red subpixel R may have the smallest area among the sub-pixels. The area of the green subpixel G may be less than the area of the blue subpixel B and may be greater than the area of the red subpixel R. The blue subpixel B, the green subpixel G, and the red subpixel R are separated from each other by the bank layer 150 (shown in FIG. 3).

The red subpixel R is disposed at the innermost side in a circular shape.

The green subpixel G is spaced apart from the red subpixel R by a predetermined distance, and is disposed outside the red subpixel R in a ring shape having a first opening a to surround the red subpixel R.

The blue subpixel B is spaced apart from the green subpixel G by a predetermined distance, and is disposed outside the green subpixel G in a ring shape having a second opening b to surround the green subpixel G. The first opening a and the second opening b are located in the same direction.

An inner surface and an outer surface of the green subpixel G are circular.

The blue subpixel B is quadrangular. Specifically, an inner surface of the blue subpixel B that faces the green subpixel G is circular, and an outer surface of the blue subpixel B is quadrangular.

The third aspect is identical in other constructions to the first aspect described with reference to FIGS. 2 and 3, and therefore a description of the identical constructions will be omitted.

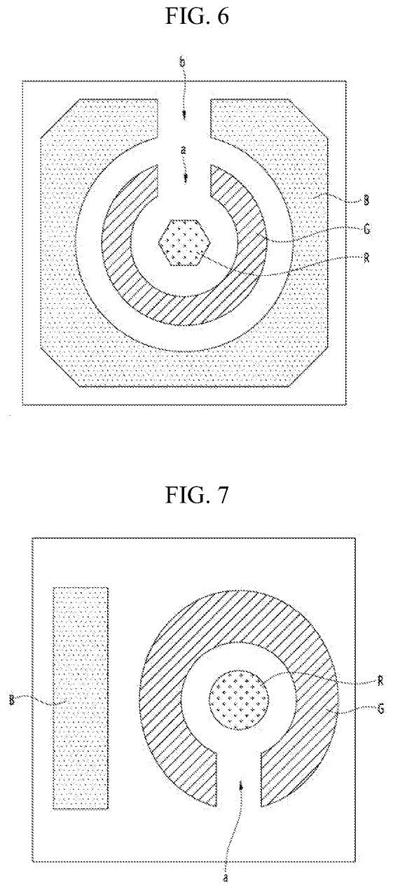

FIG. 6 is a plan view showing a unit pixel of an organic light emitting display panel according to a fourth aspect of the present disclosure.

As shown in FIG. 6, the unit pixel of the organic light emitting display panel according to the fourth aspect of the present disclosure is configured such that a blue subpixel B, a green subpixel G, and a red subpixel R are radially disposed. The blue subpixel B is disposed at the outermost side, the red subpixel R is disposed at the innermost side, and the green subpixel G is disposed between the blue subpixel B and the red subpixel R.

The blue subpixel B may have the largest area among the sub-pixels, and the red subpixel R may have the smallest area among the sub-pixels. The area of the green subpixel G may be less than the area of the blue subpixel B and may be greater than the area of the red subpixel R. The blue subpixel B, the green subpixel G, and the red subpixel R are separated from each other by the bank layer 150 (shown in FIG. 3).

The red subpixel R is disposed at the innermost side in a polygonal (hexagonal) shape.

The green subpixel G is spaced apart from the red subpixel R by a predetermined distance, and is disposed outside the red subpixel R in a ring shape having a first opening a to surround the red subpixel R.

The blue subpixel B is spaced apart from the green subpixel G by a predetermined distance, and is disposed outside the green subpixel G in a ring shape having a second opening b to surround the green subpixel G. The first opening a and the second opening b are located in the same direction.

An inner surface and an outer surface of the green subpixel G are circular.

The blue subpixel B is polygonal. Specifically, an inner surface of the blue subpixel B that faces the green subpixel G is circular, and an outer surface of the blue subpixel B is polygonal.

The fourth aspect is identical in other constructions to the first aspect described with reference to FIGS. 2 and 3, and therefore a description of the identical constructions will be omitted.

FIG. 7 is a plan view showing a unit pixel of an organic light emitting display panel according to a fifth aspect of the present disclosure.

As shown in FIG. 7, the unit pixel of the organic light emitting display panel according to the fifth aspect of the present disclosure is configured such that a green subpixel G and a red subpixel R are radially disposed and such that a rectangular blue subpixel B is disposed at one side of the green subpixel G. The green subpixel G is disposed at the outside, and the red subpixel R is disposed at the inside.

The green subpixel G may have the largest area among the sub-pixels, and the red subpixel R may have the smallest area among the sub-pixels. The area of the blue subpixel B may be less than the area of the green subpixel G and may be greater than the area of the red subpixel R. The blue subpixel B, the green subpixel G, and the red subpixel R are separated from each other by the bank layer 150 (shown in FIG. 3).

The red subpixel R is disposed at the inside in a circular shape.

The green subpixel G is spaced apart from the red subpixel R by a predetermined distance, and is disposed outside the red subpixel R in a ring shape having a first opening a to surround the red subpixel R.

The blue subpixel B is spaced apart from the green subpixel G by a predetermined distance, and is disposed at one side of the green subpixel G.

An inner surface and an outer surface of the green subpixel G are circular.

The blue subpixel B is rectangular.

The fifth aspect is identical in other constructions to the first aspect described with reference to FIGS. 2 and 3, and therefore a description of the identical constructions will be omitted.

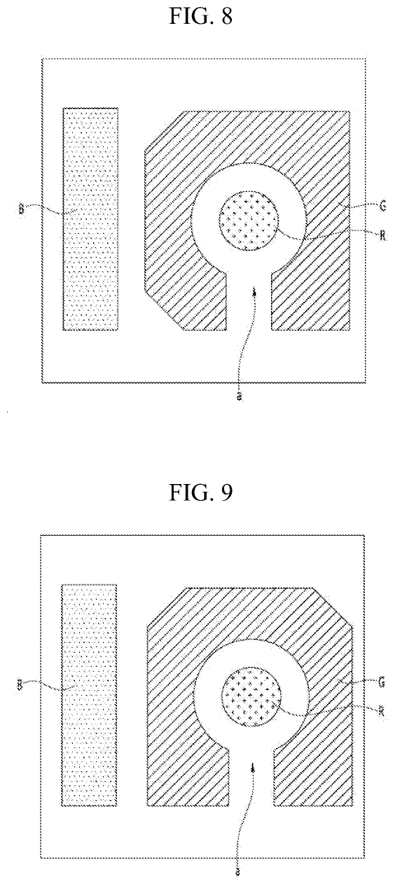

FIG. 8 is a plan view showing a unit pixel of an organic light emitting display panel according to a sixth aspect of the present disclosure.

As shown in FIG. 8, the unit pixel of the organic light emitting display panel according to the sixth aspect of the present disclosure is configured such that a green subpixel G and a red subpixel R are radially disposed and such that a blue subpixel B is disposed at one side of the green subpixel G.

The green subpixel G may have the largest area among the sub-pixels, and the red subpixel R may have the smallest area among the sub-pixels. The area of the blue subpixel B may be less than the area of the green subpixel G and may be greater than the area of the red subpixel R. The blue subpixel B, the green subpixel G, and the red subpixel R are separated from each other by the bank layer 150 (shown in FIG. 3).

The red subpixel R is disposed inside the green subpixel G in a circular shape.

The green subpixel G is spaced apart from the red subpixel R by a predetermined distance, and is disposed outside the red subpixel R in a ring shape having a first opening a to surround the red subpixel R.

The blue subpixel B is spaced apart from the green subpixel G by a predetermined distance, and is disposed at one side of the green subpixel G.

The green subpixel G is polygonal. Specifically, an inner surface of the green subpixel G is circular, and an outer surface of the green subpixel G is polygonal. In particular, a middle part of the outer surface of the green subpixel G that faces a long side of the blue subpixel B is parallel to the blue subpixel B, and opposite end parts of the outer surface of the green subpixel G are not parallel to the blue subpixel B.

The blue subpixel B is polygonal.

The sixth aspect is identical in other constructions to the first aspect described with reference to FIGS. 2 and 3, and therefore a description of the identical constructions will be omitted.

FIG. 9 is a plan view showing a unit pixel of an organic light emitting display panel according to a seventh aspect of the present disclosure.

As shown in FIG. 9, the unit pixel of the organic light emitting display panel according to the seventh aspect of the present disclosure is configured such that a green subpixel G and a red subpixel R are radially disposed and such that a blue subpixel B is disposed at one side of the green subpixel G.

The green subpixel G may have the largest area among the sub-pixels, and the red subpixel R may have the smallest area among the sub-pixels. The area of the blue subpixel B may be less than the area of the green subpixel G and may be greater than the area of the red subpixel R. The blue subpixel B, the green subpixel G, and the red subpixel R are separated from each other by the bank layer 150 (shown in FIG. 3).

The red subpixel R is disposed inside the green subpixel G in a circular shape.

The green subpixel G is spaced apart from the red subpixel R by a predetermined distance, and is disposed outside the red subpixel R in a ring shape having a first opening a to surround the red subpixel R.

The blue subpixel B is spaced apart from the green subpixel G by a predetermined distance, and is disposed at one side of the green subpixel G.

The green subpixel G is polygonal. Specifically, an inner surface of the green subpixel G is circular, and an outer surface of the green subpixel G is polygonal. In particular, a middle part of the outer surface of the green subpixel G that faces a long side of the blue subpixel B is parallel to the blue subpixel B, and one end part of the outer surface of the green subpixel G is not parallel to the blue subpixel B.

The blue subpixel B has a polygonal shape.

The seventh aspect is identical in other constructions to the first aspect described with reference to FIGS. 2 and 3, and therefore a description of the identical constructions will be omitted.

FIG. 10 is a plan view showing a unit pixel of an organic light emitting display panel according to an eighth aspect of the present disclosure.

As shown in FIG. 10, the unit pixel of the organic light emitting display panel according to the eighth aspect of the present disclosure is configured such that a green subpixel G and a red subpixel R are radially disposed and such that a blue subpixel B is disposed at one side of the green subpixel G.

The green subpixel G may have the largest area among the sub-pixels, and the red subpixel R may have the smallest area among the sub-pixels. The area of the blue subpixel B may be less than the area of the green subpixel G and may be greater than the area of the red subpixel R. The blue subpixel B, the green subpixel G, and the red subpixel R are separated from each other by the bank layer 150 (shown in FIG. 3).

The red subpixel R is disposed inside the green subpixel G in a circular shape.

The green subpixel G is spaced apart from the red subpixel R by a predetermined distance, and is disposed outside the red subpixel R in a ring shape having a first opening a to surround the red subpixel R.

The blue subpixel B is spaced apart from the green subpixel G by a predetermined distance, and is disposed at one side of the green subpixel G.

The green subpixel G is quadrangular. Specifically, an inner surface of the green subpixel G is circular, and an outer surface of the green subpixel G is quadrangular. In particular, the outer surface of the green subpixel G that faces a long side of the blue subpixel B is parallel to the blue subpixel B.

The blue subpixel B has a polygonal shape.

The eighth aspect is identical in other constructions to the first aspect described with reference to FIGS. 2 and 3, and therefore a description of the identical constructions will be omitted.

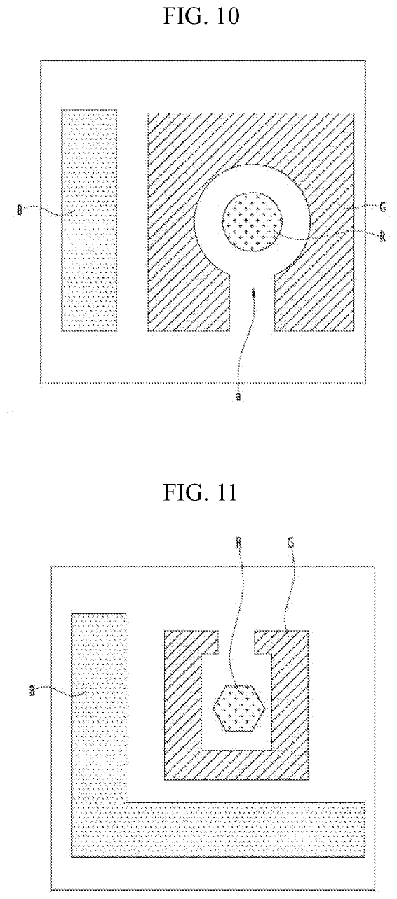

FIG. 11 is a plan view showing a unit pixel of an organic light emitting display panel according to a ninth aspect of the present disclosure.

As shown in FIG. 11, the unit pixel of the organic light emitting display panel according to the ninth aspect of the present disclosure is configured such that a green subpixel G and a red subpixel R are radially disposed and such that a blue subpixel B is disposed at one side of the green subpixel G.

The blue subpixel B may have the largest area among the sub-pixels, and the red subpixel R may have the smallest area among the sub-pixels. The area of the green subpixel G may be less than the area of the blue subpixel B and may be greater than the area of the red subpixel R. The blue subpixel B, the green subpixel G, and the red subpixel R are separated from each other by the bank layer 150 (shown in FIG. 3).

The red subpixel R is disposed at the inside in a polygonal shape.

The green subpixel G is spaced apart from the red subpixel R by a predetermined distance, and is disposed outside the red subpixel R in a ring shape having a first opening a to surround the red subpixel R.

The blue subpixel B is spaced apart from the green subpixel G by a predetermined distance, and is disposed at one side of the green subpixel G in an L shape.

The green subpixel G is quadrangular. Specifically, an inner surface of the green subpixel G that faces the red subpixel R is quadrangular, and an outer surface of the green subpixel G is also quadrangular. In particular, the outer surface of the green subpixel G that faces the blue subpixel B is parallel to the blue subpixel B.

The blue subpixel B is disposed at one side of the green subpixel G having no first opening a formed therein in an L shape.

The ninth aspect is identical in other constructions to the first aspect described with reference to FIGS. 2 and 3, and therefore a description of the identical constructions will be omitted.

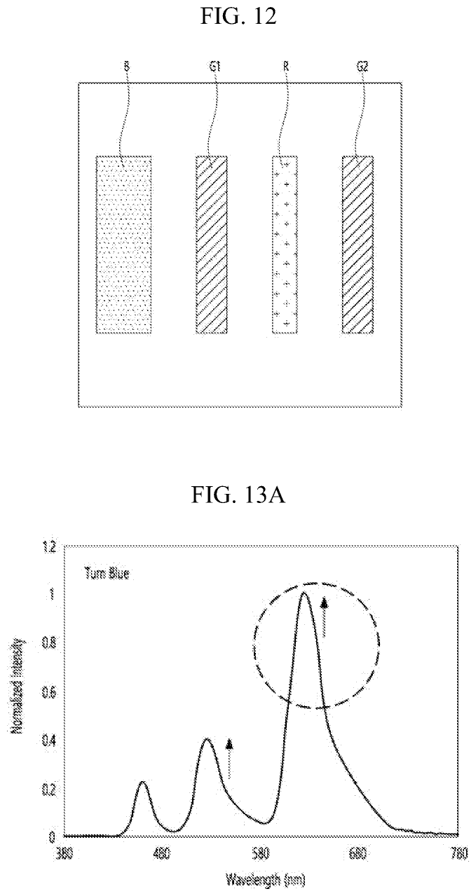

FIG. 12 is a plan view showing a unit pixel of an organic light emitting display panel according to a tenth aspect of the present disclosure.

As shown in FIG. 12, the unit pixel of the organic light emitting display panel according to the tenth aspect of the present disclosure includes a blue subpixel B, a first green subpixel G1, a second green subpixel G2, and a red subpixel R, wherein the blue subpixel B, the first green subpixel G1, the red subpixel R, and the second green subpixel G2 are disposed in the order mentioned. That is, the first green subpixel G1 and the second green subpixel G2 are disposed at opposite sides of the red subpixel R, and one of the first green subpixel G1 and the second green subpixel G2 is disposed between the blue subpixel B and the red subpixel R.

The sum of the areas of the first and second green subpixels G1 and G2 is the largest, and the area of the red subpixel R is the smallest. The area of the blue subpixel B may be less than the sum of the areas of the first and second green subpixels G1 and G2 and may be greater than the area of the red subpixel R. The blue subpixel B, the first green subpixel G1, the red subpixel R, and the second green subpixel G2 are separated from each other by the bank layer 150 (shown in FIG. 3).

Although separated from each other, the first green subpixel G1 and the second green subpixel G2 may be driven by one driving thin film transistor DT.

The tenth aspect is identical in other constructions to the first aspect described with reference to FIGS. 2 and 3, and therefore a description of the identical constructions will be omitted.

In the unit pixel of the organic light emitting display panel according to any one of the first to tenth aspects of the present disclosure, the respective subpixels are disposed in a structure in which, when a straight line is drawn in at least one direction based on the red subpixel R, the straight line reaches the blue subpixel B via the green subpixel G.

In the organic light emitting display panel according to any one of the first to tenth aspects of the present disclosure, therefore, it is possible to prevent lateral current leakage through a common layer even in a structure in which the common layer is applied.

Furthermore, even during low-gradation driving, the red subpixel adjacent to the blue subpixel is not turned on when the blue subpixel is turned on, whereby color mixing is prevented and color purity is improved.

This will be described hereinafter based on experimental results.

FIG. 13A is a spectrum showing color coordinate change at low gradation when a blue subpixel according to a comparative example is turned on, and FIG. 13B is a spectrum showing color coordinate change at low gradation when a blue subpixel to which any one of the aspects of the present disclosure is applied is turned on.

FIG. 13A shows a comparative example in which no green subpixel was disposed between the blue subpixel and a red subpixel.

As shown in FIG. 13A, even though voltage was applied between a first electrode and a second electrode of the blue subpixel B to emit pure blue light, the red subpixel R adjacent to the blue subpixel B was also turned on due to lateral current leakage through a common layer as well as a vertical electric field between a positive electrode and a negative electrode of the blue subpixel B that was turned on. That is, light having a wavelength of about 630 nm (red light) was emitted.

In contrast, as shown in FIG. 13B, voltage was applied between a first electrode and a second electrode of the blue subpixel B to emit pure blue light. Since a green subpixel G was disposed between the blue subpixel and a red subpixel R, however, lateral current leakage to the red subpixel R through a common layer did not occur. That is, light having a wavelength of about 630 nm (red light) was not emitted.

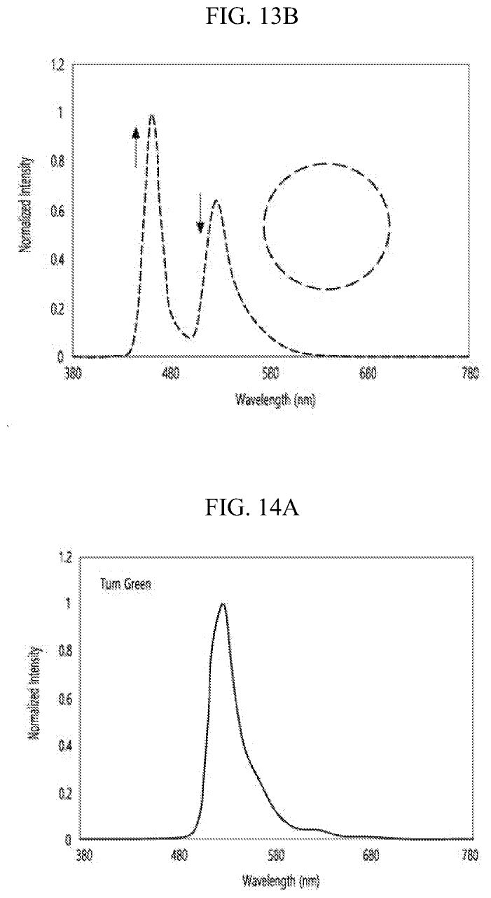

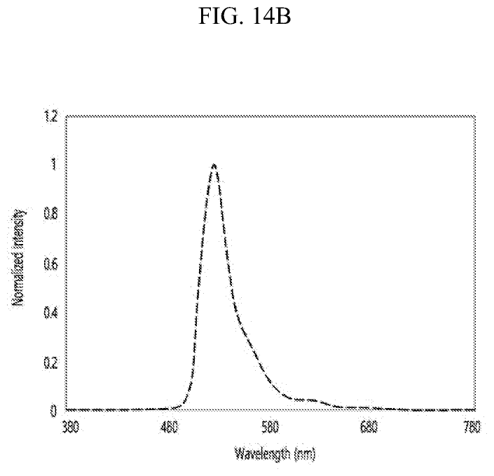

FIG. 14A is a spectrum showing color coordinate change at low gradation when a green subpixel according to a comparative example is turned on, and FIG. 14B is a spectrum showing color coordinate change at low gradation when a green subpixel to which any one of the aspects of the present disclosure is applied is turned on.

FIG. 14A shows a comparative example in which no green subpixel G was disposed between the blue subpixel B and a red subpixel R.

As shown in FIGS. 14A and 14B, no serious problem occurred when the green subpixel was turned on in the comparative example and the aspect of the present disclosure.

It may be seen from FIGS. 13A, 13B, 14A, and 14B that, when the blue subpixel and the green subpixel, which have a relatively small difference in threshold voltage therebetween, are adjacent to each other and the green subpixel is disposed between the blue subpixel and the red subpixel, which have the largest difference in threshold voltage therebetween, lateral current leakage is reduced.

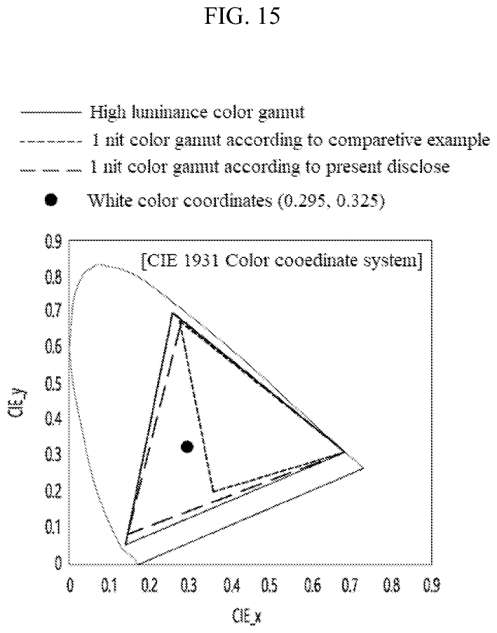

Meanwhile, FIG. 15 is a view showing CIE 1931 color coordinate systems according to a comparative example and an aspect of the present disclosure.

In all of the aspects of the present disclosure, even though lateral current leakage from the blue subpixel B to the green subpixel G or from the green subpixel G to the red subpixel R occurs, influence of color shift due to a phenomenon in which the red subpixel R is also turned on when the blue subpixel B according to the comparative example is turned on is almost excluded.

When the blue subpixel according to the aspect of the present disclosure is turned on, therefore, blue color shift occurs along a straight path that joins x_0. 1379/y_0. 0513, which are color coordinates of blue, and x_0. 2570/y_0. 6994, which are color coordinates of green.

In addition, when the green subpixel according to the aspect of the present disclosure is turned on, color shift occurs along a straight path that joins x_0. 2570/y_0. 6994 and x_0. 6868/y_0. 3120, in the same manner as in the comparative example. As a result, it may be seen that it is possible to obtain conditions advantageous to implementation of low luminance satisfying x_0. 295/y_0. 325, which are color coordinates of white according to the aspect of the present disclosure, in a color gamut.

As is apparent from the above description, an organic light emitting display panel according to an aspect of the present disclosure has the following effects.

A unit pixel of the organic light emitting display panel according to an aspect of the present disclosure is configured such that a green subpixel is disposed between a red subpixel and a blue subpixel, and therefore it is possible to prevent the red subpixel from being turned on due to lateral current leakage when the blue subpixel is turned on.

During low-gradation driving, therefore, it is possible to prevent color mixing and to improve color purity.

While the aspects of the present disclosure have been described with reference to the accompanying drawings, the present disclosure is not limited to the aspects and may be embodied in various different forms, and those skilled in the art will appreciate that the present disclosure may be embodied in specific forms other than those set forth herein without departing from the technical idea and essential characteristics of the present disclosure. The disclosed aspects are therefore to be construed in all aspects as illustrative and not restrictive. Therefore, the scope of the present disclosure is defined by the appended claims, and it should be interpreted that all alterations or modifications derived from the meaning and scope of the claims and equivalent concepts thereto are included in the scope of the present disclosure.

1. An organic light emitting display panel comprising:
a plurality of unit pixels, each unit pixel including a blue subpixel, a green subpixel, and a red subpixel radially disposed,
wherein the red subpixel is disposed at an innermost side,
the blue subpixel is disposed at an outermost side, and
the green subpixel is disposed between the blue subpixel and the red subpixel.

2. The organic light emitting display panel according to claim 1, wherein the blue subpixel has a largest area,
the red subpixel has a smallest area, and
the green subpixel has an area smaller than the blue subpixel and has an area larger than the red subpixel.

3. The organic light emitting display panel according to claim 1, wherein the red subpixel is disposed at the innermost side in a circular shape,
the green subpixel is disposed outside the red subpixel in a ring shape having a first opening to surround the red subpixel, and
the blue subpixel is disposed outside the green subpixel in a ring shape having a second opening to surround the green subpixel.

4. The organic light emitting display panel according to claim 3, wherein the first opening is located in a first direction,
the second opening is located in a second direction, and
the first direction and the second direction are identical with each other.

5. The organic light emitting display panel according to claim 3, wherein an inner surface of the green subpixel that faces the red subpixel and an outer surface of the green subpixel are circular, and
an inner surface of the blue subpixel that faces the green subpixel and an outer surface of the blue subpixel are circular.

6. The organic light emitting display panel according to claim 3, wherein an inner surface of the green subpixel that faces the red subpixel and an outer surface of the green subpixel are circular, and
an inner surface of the blue subpixel that faces the green subpixel is circular while an outer surface of the blue subpixel is polygonal.

7. The organic light emitting display panel according to claim 3, wherein an inner surface of the green subpixel that faces the red subpixel and an outer surface of the green subpixel are circular, and
an inner surface of the blue subpixel that faces the green subpixel is circular while an outer surface of the blue subpixel is quadrangular.

8. The organic light emitting display panel according to claim 3, wherein the red subpixel is polygonal,
an inner surface of the green subpixel that faces the red subpixel and an outer surface of the green subpixel are circular, and
an inner surface of the blue subpixel that faces the green subpixel is circular while an outer surface of the blue subpixel is polygonal.

9. The organic light emitting display panel according to claim 1, wherein the blue subpixel, the green subpixel, and the red subpixel are separated from each other by a bank layer.

10. An organic light emitting display panel comprising:
a plurality of unit pixels, each of the unit pixels including a green subpixel and a red subpixel radially disposed and a blue subpixel disposed at one side of the green subpixel,
wherein the red subpixel is disposed inside the green subpixel, and
wherein the green subpixel is disposed outside the red subpixel and surrounds the red subpixel.

11. The organic light emitting display panel according to claim 10, wherein the green subpixel has a largest area,
the red subpixel has a smallest area, and
the blue subpixel has an area smaller than the green subpixel and has an area larger than the red subpixel.

12. The organic light emitting display panel according to claim 10, wherein the blue subpixel has a largest area,
the red subpixel has a smallest area, and
the green subpixel has a smaller area than the blue subpixel and a larger area than the red subpixel.

13. The organic light emitting display panel according to claim 10, wherein the red subpixel is disposed at an inside in a circular shape,
the green subpixel is disposed outside the red subpixel in a ring shape having a first opening so as to surround the red subpixel, and
the blue subpixel is disposed at one side of the green subpixel having no first opening formed therein in a polygonal shape.

14. The organic light emitting display panel according to claim 13, wherein an inner surface of the green subpixel that faces the red subpixel and an outer surface of the green subpixel are circular.

15. The organic light emitting display panel according to claim 13, wherein an inner surface of the green subpixel that faces the red subpixel is circular, and
an outer surface of the green subpixel is polygonal.

16. The organic light emitting display panel according to claim 15, wherein a middle part of the outer surface of the green subpixel that faces a long side of the blue subpixel is parallel to the blue subpixel, and
opposite end parts of the outer surface of the green subpixel are not parallel to the blue subpixel.

17. The organic light emitting display panel according to claim 15, wherein a middle part of the outer surface of the green subpixel that faces a long side of the blue subpixel is parallel to the blue subpixel, and
one end part of the outer surface of the green subpixel is not parallel to the blue subpixel.

18. The organic light emitting display panel according to claim 13, wherein an inner surface of the green subpixel that faces the red subpixel is circular,
an outer surface of the green subpixel is quadrangular, and
the outer surface of the green subpixel that faces the blue subpixel is parallel to the blue subpixel.

19. The organic light emitting display panel according to claim 10, wherein the red subpixel is disposed at an inside in a polygonal shape,
the green subpixel is disposed outside the red subpixel in a ring shape having a first opening so as to surround the red subpixel, and
the blue subpixel is disposed at one side of the green subpixel having no first opening formed therein in an L shape.

20. The organic light emitting display panel according to claim 10, wherein the blue subpixel, the green subpixel, and the red subpixel are separated from each other by a bank layer.

21. An organic light emitting display panel comprising:
a plurality of unit pixels, each unit pixel including a blue subpixel, a first green subpixel, a second green subpixel, and a red subpixel,
wherein the first green subpixel and the second green subpixel are disposed at opposite sides of the red subpixel, and
one of the first green subpixel and the second green subpixel is disposed between the blue subpixel and the red subpixel.

22. The organic light emitting display panel according to claim 21, wherein the first green subpixel and the second green subpixel are driven by one driving thin film transistor.

23. The organic light emitting display panel according to claim 21, wherein the red subpixel has a smallest area, and the blue subpixel has an area smaller than a sum of areas of the first and second green subpixels and greater than the area of the red subpixel.

24. The organic light emitting display panel according to claim 21, wherein the blue subpixel, the first green subpixel, the red subpixel and the second green subpixel are separated from each other by a bank layer.
